(19) United States
(12) Patent Application Publication
(10) Pub. No.: US 2015/0130580 A1
(43) Pub. Date: May 14, 2015

(54) COMMON MODE FILTER AND MANUFACTURING METHOD THEREOF

(71) Applicant: Samsung Electro-Mechanics Co., Ltd., Suwon (KR)

(72) Inventors: Sang-Moon LEE, Suwon (KR); Ju-Hwan YANG, Suwon (KR); Hye-Won BANG, Suwon (KR); Won-Chul SIM, Suwon (KR)

(73) Assignee: Samsung Electro-Mechanics Co., Ltd., Suwon (KR)

(21) Appl. No.: 14/259,536

(22) Filed: Apr. 23, 2014

(30) Foreign Application Priority Data
Nov. 13, 2013 (KR) 10-2013-0137819

(51) Int. Cl. H03H 7/01; G03F 7/16; H01F 27/34; H01F 41/04; H01F 27/28; H01F 27/24

(52) U.S. Cl. CPC H03H 7/17; H01F 27/2804; H01F 27/24; H01F 27/34; H01F 41/041; G03F 7/16
USPC 336/200; 427/116; 430/315

(57) ABSTRACT

A common mode filter and a manufacturing method thereof are disclosed. The common mode filter in accordance with an embodiment of the present invention includes: a magnetic substrate; a coil layer formed on the magnetic substrate and including a coil pattern; a magnetic layer formed on the coil layer; a resin layer formed on the magnetic layer; and an external electrode formed in the resin layer so as to be electrically connected with the coil pattern.

### CROSS-REFERENCE TO RELATED APPLICATIONS

This application claims the benefit of Korean Patent Application No. 10-2013-0137819, filed with the Korean Intellectual Property Office on Nov. 13, 2013, the disclosure of which is incorporated herein by reference in its entirety.

### BACKGROUND

1. Technical Field

The present invention relates to a common mode filter and a method of manufacturing the common mode filter.

2. Background Art

High-speed digital interfaces, such as USB, require a part that addresses noise. One of such parts that removes common mode noise selectively is a common mode filter.

Common mode noise can occur when impedance fails to be parallel in the wiring system. The common mode noise can occur more often for higher frequency. Since the common mode noise can be also transferred to, for example, the surface of the earth and bounced back with a big loop, the common mode noise causes various kinds of noise troubles in far-away electronic devices.

The common mode filter can allow a differential mode signal to bypass while selectively removing the common mode noise. In the common mode filter, magnetic flux is canceled out by the differential mode signal, causing no inductance to occur and allowing the differential mode signal to bypass. On the other hand, magnetic flux is augmented by the common mode noise, increasing the inductance and allowing the noise to be removed.

The related art of the present invention is disclosed in Korea Patent Publication No. 2011-0129844 (COMMON MODE NOISE FILTER; laid open on Dec. 6, 2011).

### SUMMARY

The present invention provides a common mode filter, in which a resin layer is formed on a magnetic layer and an external electrode is formed on the resin layer.

An aspect of the present invention provides a common mode filter, which includes: a magnetic substrate; a coil layer formed on the magnetic substrate and including a coil pattern; a magnetic layer formed on the coil layer; a resin layer formed on the magnetic layer; and an external electrode formed in the resin layer so as to be electrically connected with the coil pattern.

The resin layer can have a roughness that is lower than that of the magnetic layer.

The resin layer can be formed to be thinner than the magnetic layer.

A seed layer can be interposed between the external electrode and the resin layer.

The magnetic layer can include a resin material and magnetic powder included in the resin material.

The resin material can be made of a same material as the resin layer.

The common mode filter can further include a ground electrode formed on the resin layer in order to discharge static electricity brought in to the external electrode.

The common mode filter can further include an electrostatic discharge member formed on the resin layer so as to be interposed between the external electrode and the ground electrode.

The common mode filter can further include a protective layer formed on the electrostatic discharge member so as to be interposed between the external electrode and the ground electrode in order to protect the electrostatic discharge member.

Another aspect of the present invention provides a method of manufacturing a common mode filter that includes: forming a coil layer including a coil pattern on a magnetic substrate; forming a magnetic layer on the coil layer; forming a resin layer on the magnetic layer; and forming an external electrode on the resin layer so as to be electrically connected with the coil pattern.

The resin layer can have a roughness that is lower than that of the magnetic layer.

The resin layer can be formed to be thinner than the magnetic layer.

The forming of the external electrode can include: coating a resist on the resin layer; forming an opening on the resist so as to correspond to the external electrode; forming a plating layer in the opening; and removing the resist.

The method can further include, prior to the coating of the resist on the resin layer, forming a seed layer on the resin layer. The plating layer can be formed on the seed layer.

The method can further include, after the removing of the resist, removing the seed layer.

The forming of the external electrode can include forming a ground electrode on the resin layer in order to discharge static electricity brought in to the external electrode.

The method can further include, after the forming of the ground electrode, forming an electrostatic discharge member on the resin layer so as to be interposed between the external electrode and the ground electrode.

The method can further include, after the forming of the electrostatic discharge member, forming a protective layer on the electrostatic discharge member so as to be interposed between the external electrode and the ground electrode in order to protect the electrostatic discharge member.

### BRIEF DESCRIPTION OF THE DRAWINGS

FIG. 1 show a common mode filter in accordance with an embodiment of the present invention.

FIG. 2 is flow diagram showing a method of manufacturing the common mode filter in accordance with an embodiment of the present invention.

FIG. 3 to FIG. 12 show the flow of the method of manufacturing the common mode filter in accordance with an embodiment of the present invention.

### DETAILED DESCRIPTION

Hereinafter, a certain embodiment of a common mode filter and a manufacturing method thereof in accordance with the present invention will be described in detail with reference to the accompanying drawings. In describing the present invention with reference to the accompanying drawings, any identical or corresponding elements will be assigned with same reference numerals, and no redundant description thereof will be provided.

Terms such as “first” and “second” can be used in merely distinguishing one element from other identical or corresponding elements, but the above elements shall not be restricted to the above terms.

When one element is described to be “coupled” to another element, it does not refer to a physical, direct contact between these elements only, but it shall also include the possibility of yet another element being interposed between these elements and each of these elements being in contact with said yet another element.

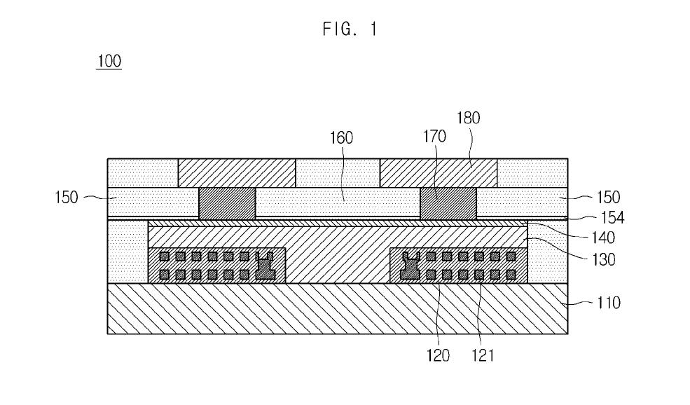

FIG. 1 show a common mode filter in accordance with an embodiment of the present invention. The common mode filter in accordance with an embodiment of the present invention can include magnetic substrate 110, coil layer 120, magnetic layer 130, resin layer 140, external electrode 150, ground electrode 160, electrostatic discharge member 170 and protective layer 180.

The magnetic substrate 110 is a board that is magnetic and is placed at a lowermost location of the common mode filter. The magnetic substrate 110 can include at least one of metal, polymer and ceramic, which are magnetic materials.

The coil layer 120 can be formed on the magnetic substrate 110 and can include a coil pattern 121, which includes coils and functions as an inductor. Each coil in the coil pattern 121 can be formed in a helical shape and can be formed to be adjacent to but not to overlap with another coil. As the helical shape of coil in the coil pattern 121 can make the length of the coil elongated, inductance can be increased.

The coil pattern 121 can include dual layers of coils. Each coil in the first layer is in the shape of winding in from an outside to an inside while each coil in the second layer is in the shape of winding out from an inside to an outside.

The coils in the coil pattern 121 can be formed in pairs. Magnetic coherence occurs in between the pair of coils of the coil pattern 121. In the case of common mode noise, the inductance becomes augmented as the magnetic flux occurred by the common mode noise is combined. As a result, the noise can be removed.

The coil pattern 121 can be made of copper (Cu) or aluminum (Al), which is highly conductive and workable. Moreover, the coil pattern 121 can be formed through photolithography and plating.

The coil layer 121 can include a dielectric layer. More specifically, the coil layer 120 can include a dielectric layer that encompasses the coil pattern 121. In such a case, the coil pattern 121 can be formed to be surrounded by the dielectric layer. The dielectric layer can insulate the coil pattern 121 from the magnetic substrate 110. The dielectric layer can be formed on the magnetic substrate 110. Preferably used as a material for the dielectric layer can be polymer resin, for example, epoxy resin or polyimide resin, which has a good electrical insulation property and is highly workable.

The dielectric layer can be partially formed before the coil pattern 121 is formed, and then another portion of the dielectric layer can be successively formed after the coil pattern 121 is formed so as to cover the coil pattern 121. Accordingly, the dielectric layer can cover all of an upper part, a lower part and side surfaces of the coil pattern 121.

The magnetic layer 130 is a layer that is formed on the coil layer 120 and is magnetic. The magnetic layer 130 forms a closed-magnetic circuit together with the magnetic substrate 110. Magnetic coupling of the coil pattern 121 can be enhanced by the strong magnetic flux formed by the magnetic layer 130 and the magnetic substrate 110.

The magnetic layer 130 can include magnetic powder and resin material. The magnetic powder allows the magnetic layer to be magnetic, and the resin material allows the magnetic layer 130 to have fluidity. In such a case, the magnetic powder can include ferrite. The resin material of the magnetic layer 130 can be epoxy resin, in which novolak, bisphenol A, phenoxy, etc. are combined. The magnetic powder can take 65 Vol % of the entire magnetic layer 130.

The resin layer 140 is a layer that is formed on the magnetic layer 130 and does not include magnetic powder. Here, the resin layer 140 can be epoxy resin, in which novolak, bisphenol A, phenoxy, etc. are combined, and can be the same resin material of the magnetic layer 130. The resin layer 140 can enhance adhesion between the magnetic layer 130 and the external electrode 150.

The resin layer 140 can be formed to be thinner than the magnetic layer 130. The resin layer 140 does not contain magnetic powder and thus has a very low magnetic permeability. Therefore, by forming the magnetic layer 130, which has a relatively higher magnetic permeability, to be thicker than the resin layer 140, the overall magnetic permeability can be increased.

The resin layer 140 can have a smaller roughness than the magnetic layer 130. Since the resin layer 140 does not contain magnetic powder, the resin layer 140 can have a smaller roughness that the magnetic layer 130, which contains magnetic powder.

The size of magnetic powder is approximately 13.7 um, and the roughness of the magnetic layer 130 can be approximately 2.58 um, and the roughness of the resin layer 140 can be approximately 0.50 um, which is smaller than 1 um, when the roughness of the magnetic layer 130 taking up 49% of the volume is compared with the resin layer 140, which does not contain magnetic powder. In other words, the flatness of the resin layer 140 can be improved. Accordingly, forming the resin layer 140 can be helpful for forming a seed layer 154 or a resist layer 151, which will be described later.

The external electrode 150 can be formed on the resin layer 140 so as to be electrically connected with the coil pattern 121. The external electrode 150 is configured for inputting a signal to the coil pattern 121 and outputting a signal from the coil pattern 121. The external electrode 150 can be made of a conductive material, for example, copper (Cu). If the coil pattern 121 is formed with a pair of coils, the electrode 150 can be formed in two pairs.

The ground electrode 160 is configured for discharging static electricity brought in to the external electrode 150 and can be formed on the resin layer 140. In the case where the external electrode 150 is formed in two pairs, the ground electrode 160 can be formed in between every pair of external electrodes 150. The ground electrode 160 can be made of a conductive material, for example, copper (Cu).

Formed in between the external electrode 150 and the resin layer 140 can be the seed layer 154. In case the external electrode 150 is formed by plating, the seed layer 154 can be formed on the resin layer 140, and the external electrode 150 can be plated on the seed layer 154. The seed layer 154 can be made of the same material as the external electrode 150.

In case the seed layer 154 is formed between the external electrode 150 and the resin layer 140, it is possible to secure the reliability for deposition of the seed layer 154 because the resin layer 140 has a lower roughness than the magnetic layer 130. Accordingly, it is possible to secure adhesion between the resin layer 140 and the external electrode 150 formed on the seed layer 154 and to improve an external appearance by reducing defects caused by, for example, smeared plating.

The electrostatic discharge member 170 is a material that basically has a high resistance but quickly drops the resistance in case a high voltage is surged in. The electrostatic discharge member 170 can be placed between the external electrode 150 and the ground electrode 160.

The protective layer 180 can be formed on the electrostatic discharge member 170 and protect the electrostatic discharge member 170. The protective layer 180 can include magnetic powder, for example, ferrite. The protective layer 180 can function as a buffer from temperature change and can prevent a crack by enhancing the mechanical strength.

As described above, in the common mode filter 100 in accordance with an embodiment of the present invention, adhesion of the external electrode 150 and the ground electrode 160 to the magnetic layer 130 can be enhanced by the resin layer 140.

Hitherto, the common mode filter 100 in accordance with an embodiment of the present invention has been described. Hereinafter, a method of manufacturing the common mode filter 100 in accordance with an embodiment of the present invention will be described.

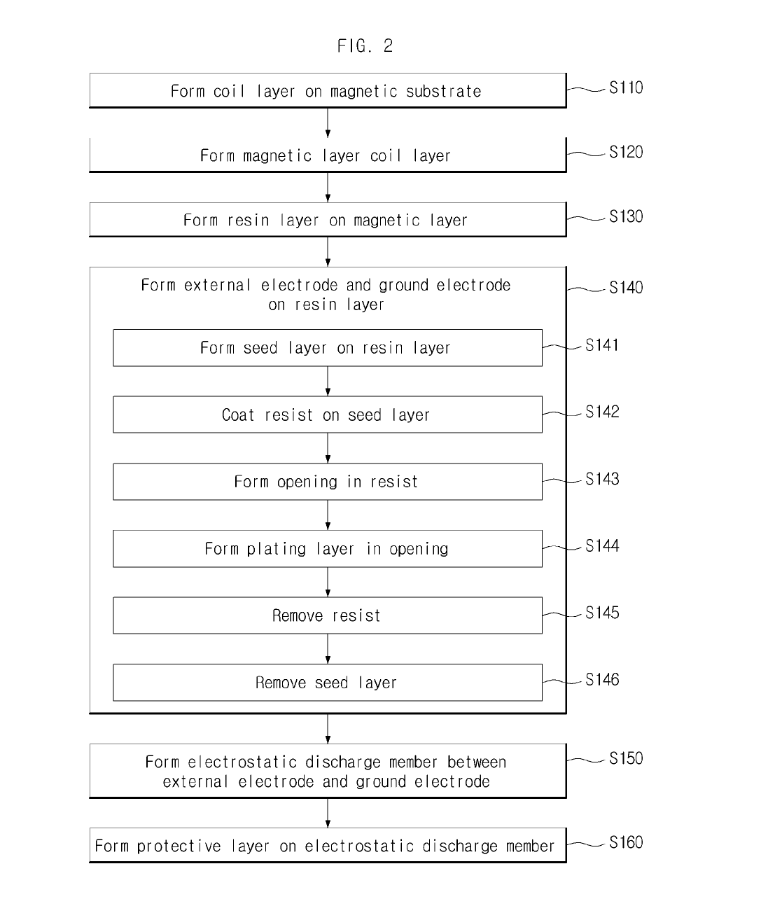

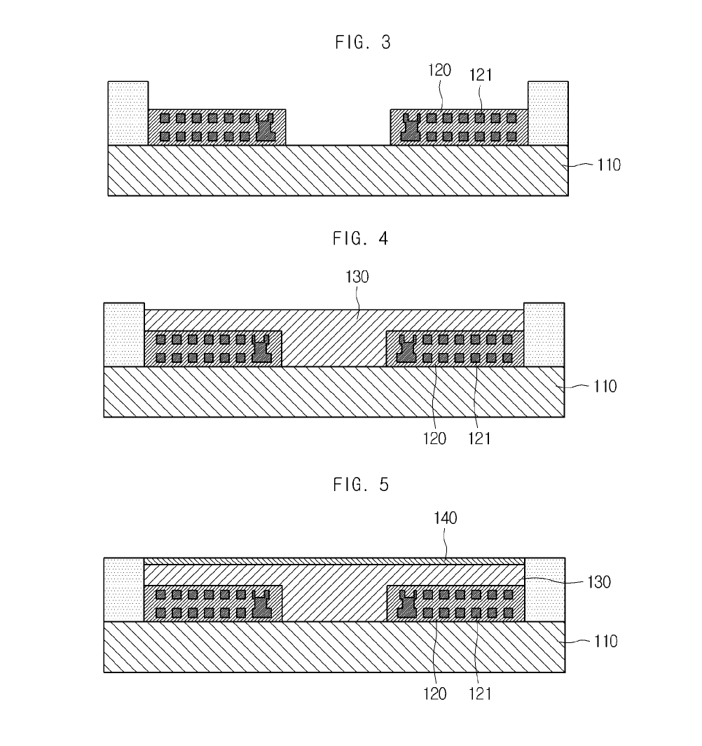

FIG. 2 is a flow diagram showing a method of manufacturing the common mode filter 100 in accordance with an embodiment of the present invention, and FIG. 3 to FIG. 12 show the flow of the method of manufacturing the common mode filter 100 in accordance with an embodiment of the present invention.

Referring to FIG. 2, the method of manufacturing the common mode filter 100 in accordance with an embodiment of the present invention can include: forming a coil layer 120 on a magnetic substrate 110 (S110); forming a magnetic layer 130 on the coil layer 120 (S120); forming a resin layer 140 on the magnetic layer 130 (S130); forming an external electrode 150 and a ground electrode 160 on the resin layer 140 (S140); forming an electrostatic discharge member 170 between the external electrode 150 and the ground electrode 160 (S150); and forming a protective layer 180 on the electrostatic discharge member 170 (S160).

Referring to FIG. 3, in the step of forming the coil layer 120 on the magnetic substrate 110 (S110), the coil layer 120 having a coil pattern 121 therein is formed on the magnetic substrate 110. The magnetic substrate 110 and the coil layer 120 have been described above. Here, a stud for electrical connection with the coil pattern 121 can be formed together with the coil layer 120. The stud can be formed vertically from the magnetic substrate 110.

Referring to FIG. 4, in the step of forming the magnetic layer 130 on the coil layer 120 (S120), the magnetic layer 130 constituted with a resin material and magnetic powder is formed on the coil layer 120. The magnetic layer 130 has fluidity due to the resin material and is injected on the coil layer 120. The injected magnetic layer 130 can be leveled and cured. Here, the magnetic layer 130 can be formed to be lower than the stud.

Referring to FIG. 5, in the step of forming the resin layer 140 on the magnetic layer 130 (S 130), the resin layer 140 having no magnetic powder therein is formed on the magnetic layer 130. The resin layer 140 can be coated on the magnetic layer 130 and cured after being leveled. The resin layer 140 can be formed to be thinner than the magnetic layer 130.

The resin layer 140 can less rough than the magnetic layer 130, and adhesion with the external electrode 150 can be enhanced by the less rough resin layer 140.

In the step of forming the external electrode 150 and the ground electrode 160 on the resin layer 140 (S140), the external ground 150, which is electrically connected with the coil pattern 121, and the ground electrode 160, which discharges static electricity brought in to the external electrode 150, are formed on the resin layer 140. The external electrode 150 can be constituted with four electrodes, and the ground electrode 160 can be constituted with two electrodes that are each formed between the electrodes constituting the external electrode 150.

The external electrode 150 and the ground electrode 160 can be made of a conductive material, and can be made of a same material, for example, copper (Cu).

The step of forming the external electrode 150 and the ground electrode 160 on the resin layer 140 (S140) can include: forming a seed layer 154 on the resin layer 140 (S141); coating a resist 151 on the seed layer (S142); forming an opening 152 in the resist 151 (S143); forming a plating layer 153 in the opening 152 (S144); removing the resist 151 (S145); and removing the seed layer 154 (S146).

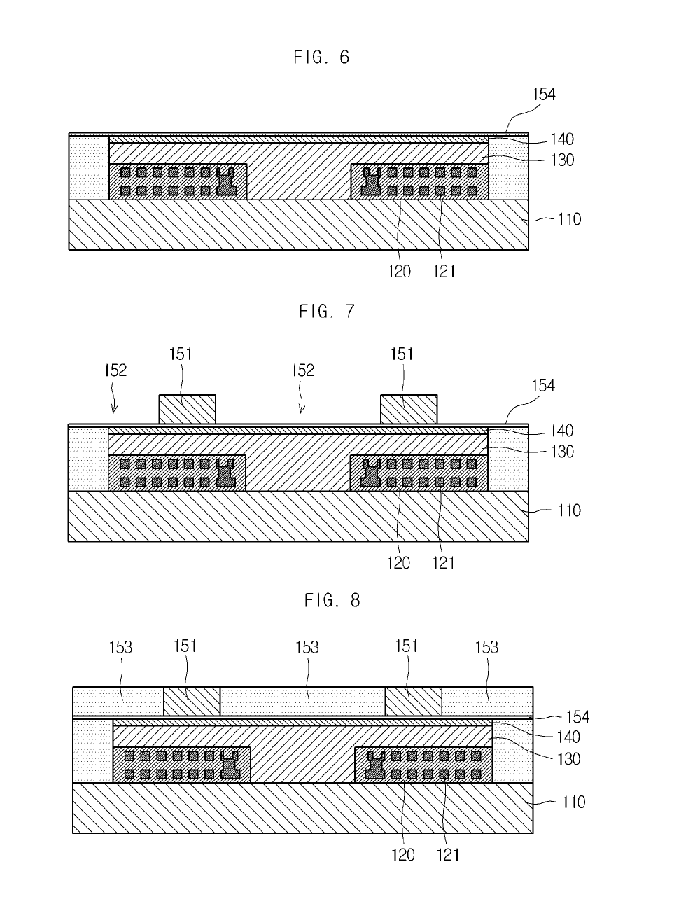

Referring to FIG. 6, in the step of forming the seed layer 154 on the resin layer 140 (S141), the seed layer 154 is formed on the resin layer 140 before the external electrode 150 and the ground electrode 160 are formed, in case the external electrode 150 and the ground electrode 160 are formed by plating.

Referring to FIG. 7, in the step of coating the resist 151 on the seed layer 154, the resist 151 is formed on the seed layer 154 in order to pattern the external electrode 150 and the ground electrode 160. The seed layer 154 can be made of a same material as the stud. Reliability can be provided by the resin layer 140 for forming the seed layer 154.

The resist 151 can be formed without forming the seed layer 154. In such a case, adhesion of the resist 151 can be enhanced by the resin layer 140.

Moreover, in the step of forming the opening 152 in the resist 151 (S143), the opening 152 is formed at a position corresponding to where the external electrode 150 and the ground electrode 160 are formed.

Referring to FIG. 8, in the step of forming the plating layer 153 in the opening 152 (S144), the plating layer 153 is formed in the opening 152 in order to form the external electrode 150 and the ground electrode 160. The plating layer 153 can be made of a same material as the seed layer 154.

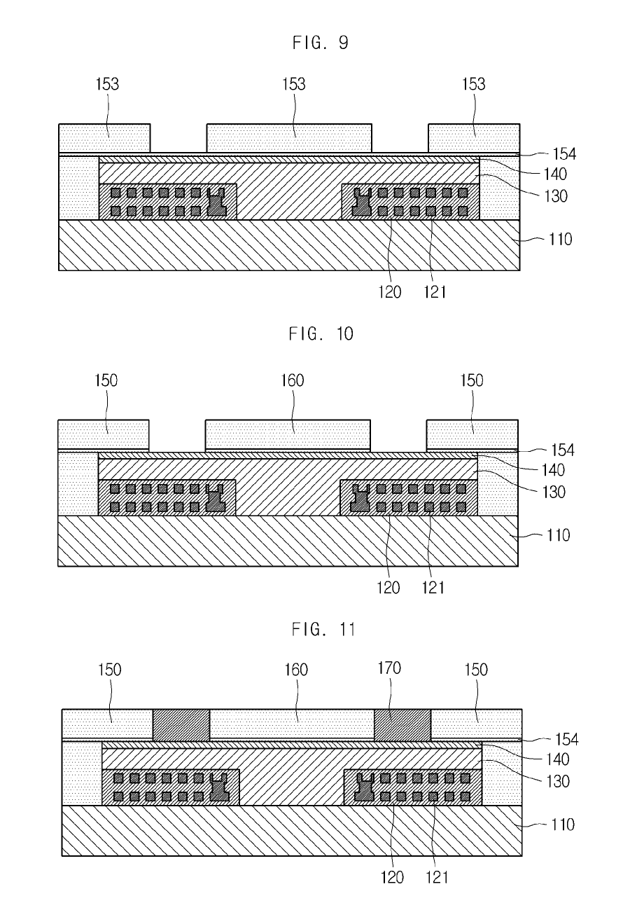

Referring to FIG. 9, in the step of removing the resist 151 (S145), the resist 151 is removed after the plating layer 153 is formed, whereas the resist 151 can be peeled off. In such a case, the seed layer 154 in the opening 152 can be exposed.

Referring to FIG. 10, in the step of removing the seed layer 154 (S146), the seed layer 154 exposed by the opening 152 is removed. In such a case, the seed layer 154 can be etched off. By this, the plating layer 153 can become the external electrode 150 or the ground electrode 160.

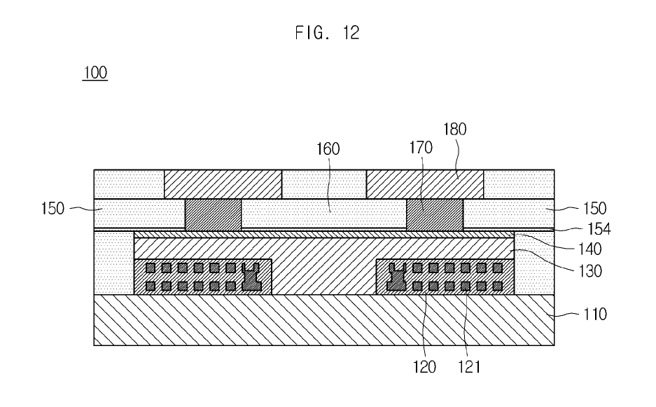

Referring to FIG. 11, in the step of forming the electrostatic discharge member 170 between the external electrode 150 and the ground electrode 160 (S150), the electrostatic discharge member 170, which drops the resistance thereof to allow a surge to flow out to the ground electrode 160 if the surge, such as static electricity, is brought in to the external electrode 150, is formed between the external electrode 150 and the ground electrode 160.

The electrostatic discharge member 170 can be printed by a screen printing method. The electrostatic discharge member 170 can be printed while the electrostatic discharge member 170 is in a fluid state and can be fixed after being cured. After the electrostatic discharge member 170 is cured, the electrostatic discharge member 170 can be surface-polished and leveled.

Referring to FIG. 12, in the step of forming the protective layer 180 on the electrostatic discharge member 170 (S160), the protective layer 180 configured for protecting the electrostatic discharge member 170 is formed on the electrostatic discharge member 170. The protective layer 180 can include ferrite, and can prevent a crack from occurring because the mechanical strength thereof is enhanced by the protective layer 180. When the protective layer 180 is formed, the external electrode 150 and the ground electrode 160 can be extended by as much as the height of the protective layer 180. Accordingly, the external electrode 150 and the ground electrode 160 can be exposed.

As described above, in the method of manufacturing the common mode filter 100 in accordance with an embodiment of the present invention, the resin layer 140 is interposed between the magnetic layer 130 and the external and ground electrodes 150, 160, and the adhesion of the seed layer 154 or the resist 151 can be enhanced by the resin layer 140.

Although a certain embodiment of the present invention has been described hitherto, it shall be appreciated that the present invention can be variously modified and permutated by those of ordinary skill in the art to which the present invention pertains by supplementing, modifying, deleting and/or adding an element without departing from the technical ideas of the present invention, which shall be defined by the claims appended below. It shall be also appreciated that such modification and/or permutation are also included in the claimed scope of the present invention.

What is claimed is:

1. A common mode filter comprising:
a magnetic substrate;
a coil layer formed on the magnetic substrate and including a coil pattern;
a magnetic layer formed on the coil layer;
a resin layer formed on the magnetic layer; and
an external electrode formed in the resin layer so as to be electrically connected with the coil pattern.

2. The common mode filter of claim 1, wherein the resin layer has a roughness that is lower than that of the magnetic layer.

3. The common mode filter of claim 1, wherein the resin layer is formed to be thinner than the magnetic layer.

4. The common mode filter of claim 1, wherein a seed layer is interposed between the external electrode and the resin layer.

5. The common mode filter of claim 1, wherein the magnetic layer includes a resin material and magnetic powder included in the resin material.

6. The common mode filter of claim 5, wherein the resin material is made of a same material as the resin layer.

7. The common mode filter of claim 1, further comprising a ground electrode formed on the resin layer in order to discharge static electricity brought in to the external electrode.

8. The common mode filter of claim 7, further comprising an electrostatic discharge member formed on the resin layer so as to be interposed between the external electrode and the ground electrode.

9. The common mode filter of claim 8, further comprising a protective layer formed on the electrostatic discharge member so as to be interposed between the external electrode and the ground electrode in order to protect the electrostatic discharge member.

10. A method of manufacturing a common mode filter, comprising:
forming a coil layer including a coil pattern on a magnetic substrate;
forming a magnetic layer on the coil layer;
forming a resin layer on the magnetic layer; and
forming an external electrode on the resin layer so as to be electrically connected with the coil pattern.

11. The method of claim 10, wherein the resin layer has a roughness that is lower than that of the magnetic layer.

12. The method of claim 10, wherein the resin layer is formed to be thinner than the magnetic layer.

13. The method of claim 10, wherein the forming of the external electrode comprises:
coating a resist on the resin layer;
forming an opening on the resist so as to correspond to the external electrode;
forming a plating layer in the opening; and
removing the resist.

14. The method of claim 13, further comprising, prior to the coating of the resist on the resin layer, forming a seed layer on the resin layer, and
wherein the plating layer is formed on the seed layer.

15. The method of claim 14, further comprising, after the removing of the resist, removing the seed layer.

16. The method of claim 10, wherein the forming of the external electrode comprises forming a ground electrode on the resin layer in order to discharge static electricity brought in to the external electrode.

17. The method of claim 16, further comprising, after the forming of the ground electrode, forming an electrostatic discharge member on the resin layer so as to be interposed between the external electrode and the ground electrode.

18. The method of claim 17, further comprising, after the forming of the electrostatic discharge member, forming a protective layer on the electrostatic discharge member so as to be interposed between the external electrode and the ground electrode in order to protect the electrostatic discharge member.
